(19) United States
(12) Patent Application Publication
(10) Pub. No.: US 2018/0182809 A1
(43) Pub. Date: Jun. 28, 2018

(54) INTEGRATED CIRCUITS INCLUDING MAGNETIC RANDOM ACCESS MEMORY STRUCTURES AND METHODS FOR FABRICATING THE SAME

(71) Applicant: Globalfoundries Singapore Pte. Ltd., Singapore (SG)

(72) Inventors: Hongxi Liu, Singapore (SG); Chenchen Jacob Wang, Singapore (SG); Yew Tuck Clament Chow, Singapore (SG); Narayanapillai Kulothungasagaran, Singapore (SG); Yong Wee Francis Poh, Singapore (SG); Jin Ho Lee, Singapore (SG); Jianbo Yang, Singapore (SG)

(21) Appl. No.: 15/392,262

(22) Filed: Dec. 28, 2016

(51) Int. Cl. H01L 27/22; H01L 43/02; H01L 43/12

(52) U.S. Cl. CPC H01L 27/224; H01L 43/12; H01L 43/02

(57) ABSTRACT

Integrated circuits and methods for fabricating integrated circuits are provided herein. In an embodiment, the integrated circuit includes a plurality of magnetic random access memory (MRAM) structures. Each of the MRAM structures includes a bottom electrode. The MRAM structures further include a magnetic tunnel junction stack (MTJ stack) overlying and in electrical communication with the bottom electrode. The MRAM structures also include a top electrode layer overlying and in electrical communication with the MTJ stack. The integrated circuit further includes a spin-on dielectric layer at least partially encapsulating the MRAM structures with the spin-on dielectric layer disposed between adjacent MRAM structures.

### TECHNICAL FIELD

The technical field generally relates to integrated circuits, and more particularly relates to integrated circuits with magnetic random access memory (MRAM) structures.

### BACKGROUND

Magnetic random access memory (MRAM) is a non-volatile computer memory technology based on magnetoresistance. MRAM differs from volatile random access memory (RAM) in several respects. Because MRAM is non-volatile, MRAM can maintain memory content when the memory device is not powered. Though non-volatile RAM is typically slower than volatile RAM, MRAM has read and write response times that are comparable to that of volatile RAM. Unlike typical RAM technologies that store data as electric charge, MRAM data is stored by magnetoresistive elements. Generally, the magnetoresistive elements are made from two magnetic layers, each of which holds a magnetization. The two magnetic layers are separated from one another by an insulating barrier layer. Together, the two magnetic layers and the barrier layer are referred to as a “magnetic tunnel junction” (“MTJ”). The magnetization of one of the magnetic layers (e.g., the “pinned layer” or “fixed layer”) is fixed in its magnetic orientation, and the magnetization of the other layer (e.g., the “free layer”) can be changed by an external magnetic field generated by a programming current or spin-polarized current through spin transfer torque effect. Thus, the magnetic field of the programming current or spin-polarized current can cause the magnetic orientations of the two magnetic layers to be either parallel, giving a lower electrical resistance across the layers (logic 0), or antiparallel, giving a higher electrical resistance across the layers (logic 1). The switch in the magnetic orientation of the free layer and the resulting high or low resistance states across the magnetic layers thus enables programming of the typical MRAM cell.

Conventional MRAM structures and methods for fabricating such structures utilize planarization processes, such as chemical-mechanical planarization (CMP), to planarize a hardmask layer overlying a top electrode layer of the MRAM structure. However, these planarization processes can adversely affect the structure and uniformity of the MRAM structures, and other structures proximate the MRAM structures. For example, CMP of the hardmask layer overlying the top electrode can result in delamination of components of the MRAM structures from the MRAM structures. As another example, the pressures induced by CMP can result in magnetic degradation of the free layer of the MTJ stack.

Further, conventional hardmask materials are utilized to form the hardmask layer overlying the top electrode layer. These conventional hardmask materials generally conform to the structural irregularities of the integrated circuits, including the MRAM structures and other structures proximate the MRAM structures. The hardmask layer formed from the conforming hardmask material will, as a result, exhibit a top surface with a lack of uniformity representative of the irregularity of the underlying features. For example, even after utilizing CMP to form a uniform top surface, variations in zone pressures applied during CMP may result in contour variations that can impact the formation of contacts on the top surface. In particular, trench formation for the contacts can extend too far within the MTJ stack, thereby rendering the MRAM structure inoperative. As another example, portions of the integrated circuit including MRAM structures and portions including other structures, such as logic portions, may also exhibit a top surface of the hardmask layer with a lack of uniformity representative of the irregularity of the MRAM structures in relation to the logic portions.

Accordingly, it would be desirable to provide integrated circuits and methods for fabricating integrated circuits with MRAM structures that with minimized susceptibility to damage during common BEOL processes. Furthermore, other desirable features and characteristics of the present disclosure will become apparent from the subsequent detailed description and the appended claims, taken in conjunction with the accompanying drawings and the foregoing technical field and background.

### BRIEF SUMMARY

Integrated circuits and methods for fabricating integrated circuits are provided herein. In an embodiment, the integrated circuit includes a plurality of magnetic random access memory (MRAM) structures. Each of the MRAM structures includes a bottom electrode. The MRAM structures further include a magnetic tunnel junction stack (MTJ stack) overlying and in electrical communication with the bottom electrode. The MRAM structures also include a top electrode layer overlying and in electrical communication with the MTJ stack. The integrated circuit further includes a spin-on dielectric layer at least partially encapsulating the MRAM structures with the spin-on dielectric layer disposed between adjacent MRAM structures.

In another embodiment, a method for fabricating an integrated circuit including a plurality of magnetic random access memory (MRAM) structures is also provided herein. The method includes forming the MRAM structures. The MRAM structures are formed by forming a bottom electrode layer, forming a magnetic tunnel junction stack (MTJ stack) overlying and in electrical communication with the bottom electrode layer, and forming a top electrode layer overlying and in electrical communication with the MTJ stack. The method further includes depositing a spin-on dielectric material to form a spin-on dielectric layer at least partially encapsulating the MRAM structures with the spin-on dielectric layer disposed between adjacent MRAM structures.

### BRIEF DESCRIPTION OF THE DRAWINGS

The present disclosure will hereinafter be described in conjunction with the following drawing Figures, wherein like numerals denote like elements, and wherein:

FIGS. 1-11 illustrate, in cross section, integrated circuits with MRAM structures and methods for fabricating integrated circuits with MRAM structures in accordance with exemplary embodiments of the present disclosure.

### DETAILED DESCRIPTION

The following detailed description is merely illustrative in nature and is not intended to limit the embodiments of the subject matter or the application and uses of such embodiments. Furthermore, there is no intention to be bound by any expressed or implied theory presented in the preceding technical field, background, brief summary or the following detailed description.

Embodiments of the present disclosure are generally directed to integrated circuits with magnetic random access memory structures and methods for fabricating integrated circuits with magnetic random access memory structures. For the sake of brevity, conventional techniques related to conventional device fabrication may not be described in detail herein. Moreover, the various tasks and processes described herein may be incorporated into a more comprehensive procedure or process having additional functionality not described in detail herein. In particular, various techniques in semiconductor fabrication processes are well-known and so, in the interest of brevity, many conventional techniques will only be mentioned briefly herein or will be omitted entirely without providing the well-known process details. Further, it is noted that integrated circuits include a varying number of components and that single components shown in the illustrations may be representative of multiple components. In particular, various steps in the manufacture of semiconductor-based memory structures are well-known and so, in the interest of brevity, many conventional steps will only be mentioned briefly herein or will be omitted entirely without providing the well-known process details.

The drawings are semi-diagrammatic and not to scale and, particularly, some of the dimensions are for the clarity of presentation and are shown exaggerated in the drawings. Similarly, although the views in the drawings for ease of description generally show similar orientations, this depiction in the drawings is arbitrary. Generally, the integrated circuit can be operated in any orientation. As used herein, it will be understood that when a first element or layer is referred to as being “over,” “overlying,” “under,” or “underlying” a second element or layer, the first element or layer may be directly on the second element or layer, or intervening elements or layers may be present where a straight line can be drawn through and between features in overlying relationship. When a first element or layer is referred to as being “on” a second element or layer, the first element or layer is directly on and in contact with the second element or layer. Further, spatially relative terms, such as “upper,” “over,” “lower,” “under,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as being “under” other elements or features would then be oriented “above” the other elements or features. Thus, the exemplary term “under” can encompass either an orientation of above or below. The device may be otherwise oriented (rotated 90 degrees or at other orientations) and the spatially relative descriptors used herein may likewise be interpreted accordingly.

As used herein, the term “substantially” refers to the complete, or nearly complete, extent or degree of an action, characteristic, property, state, structure, item, or result. As an arbitrary example, an object that is “substantially” enclosed would mean that the object is either completely enclosed or nearly completely enclosed so as to have the same overall result as if the object were completely enclosed.

FIGS. 1-11 illustrate, in cross section, integrated circuits 10 including a plurality of MRAM structures 20 and methods for fabricating integrated circuits 10 including a plurality of MRAM structures 20 in accordance with exemplary embodiments of the present disclosure. In embodiments, the integrated circuits 10 further include a logic portion 22 where no MRAM structure 20 is formed and where a through dielectric via can be formed to connect structures that are above and below the metallization levels shown in the figures. It is to be appreciated that any description of elements herein being stated as singular, as they relate to the MRAM structures 20 and the logic portion 22, may also be contemplated as plural, and vise-versa. With attention to FIG. 1, the cross-sectional view illustrates a first interlayer dielectric layer (ILD layer) 24 with a plurality of metallization features of a metallization layer 26 disposed within the first ILD layer 24. In one embodiment, the first ILD layer 24 is formed of one or more low-k dielectric materials, and/or materials such as un-doped silicate glass (USG), silicon nitride, silicon oxynitride, or other commonly used materials. The dielectric constants (k value) of the low-k dielectric materials may be less than about 3.9, for example, less than about 2.8. The first ILD layer 24 is formed using conventional deposition techniques, which depend on the particular material employed. In an exemplary embodiment, the first ILD layer 24 includes, and/or is formed from, a silicon oxide material and is formed by chemical vapor deposition (CVD) process or a plasma-enhanced CVD process in which tetraethyl orthosilicate (TEOS) is used as a reactant.

Though not illustrated for simplicity in the Figures, the first ILD layer 24 may be formed overlying an active region of a semiconductor substrate forming part of the integrated circuit 10 and including various microelectronic elements (not shown).

The metallization layer 26 may include a conductive material compatible with the particular BEOL processes employed. For example, in one embodiment, the metallization layer 26 includes a copper-containing material. In this embodiment, the metallization layer 26 is formed using a conventional damascene process. That is, trenches or cavities for the metallization layer 26 are formed in the first ILD layer 24. The copper-containing material is then deposited overlying the first ILD layer 24 to overfill the trenches or cavities, and the excess copper-containing material is removed by polishing (such as chemical mechanical polishing), such that an upper surface of the metallization layer 26 and an upper surface of the first ILD layer 24 are substantially co-planar, as illustrated. In another embodiment, the metallization layer 26 includes a conductive material that is not required to be formed through a damascene process, such as aluminum. In this embodiment, a layer of an aluminum-containing material may be formed overlying the first ILD layer 24 to form the metallization layer 26 and then etched into the desired shape to form the metallization features. Additional ILD material is then deposited alongside the metallization layer 26 resulting in the structure as shown in FIG. 1. Regardless of the material employed, the metallization layer 26 may be formed using conventional deposition techniques, such as physical vapor deposition (PVD).

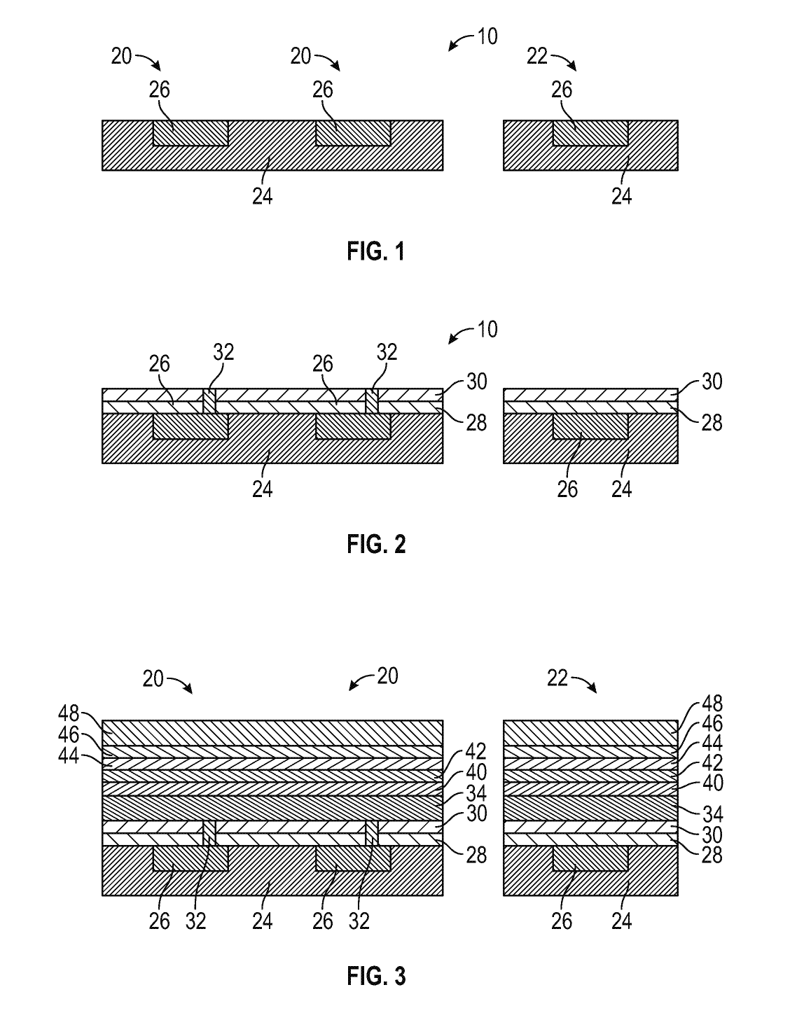

With reference now to FIG. 2, a passivation layer 28 may be formed overlying the upper surfaces of the metallization layers 26 and the first ILD layer 24. In one embodiment, the passivation layer 28 is formed of a non-organic material selected from un-doped silicate glass (USG), silicon nitride, silicon oxynitride, silicon oxide, or combinations thereof. In embodiments, the passivation layer 28 is formed from a material having a different etch selectivity in an etchant as compared to the first ILD layer 24. In an alternative embodiment, the passivation layer 28 is formed of a polymer, such as an epoxy, polyimide, benzocyclobutene (BCB), polybenzoxazole (PBO), or the like, although other organic dielectric materials may also be used. In a particular embodiment, the passivation layer 28 is formed of a silicon carbide-based passivation material including nitrogen. For example, silicon carbide with nitrogen deposited using CVD from a trimethylsilane source, which is commercially available from Applied Materials (Santa Clara, Calif., USA) under the trade name of BLOK®, is used as the passivation layer 28.

A second ILD layer 30 may be formed overlying the passivation layer 28. The second ILD layer 30 may be formed of the same materials mentioned above for the first ILD layer 24. The second ILD layer 30 is formed using conventional deposition techniques, which depend on the particular material employed.

A plurality of conductive via structures 32 may be formed extending through both the passivation layer 28 and the second ILD layer 30. The conductive via structures 32 may be disposed on and in electrical communication with the metallization features of the metallization layers 26. Each of the conductive via structures 32 may be formed by etching a cavity (not shown) through the passivation layer 28 and the second ILD layer 30 to expose a portion of the upper surface of the metallization features of the metallization layer 26 and filling the cavity with a conductive material. In this regard, known photolithographic patterning and etching procedures are used to form the cavity through the passivation layer 28 and the second ILD layer 30. That is, a photoresist layer (not separately illustrated) is deposited overlying the second ILD layer 30 and then is exposed to form an image pattern, followed by application of a developing solution to form pattern openings within the photoresist layer. With the photoresist layer thus patterned, the second ILD layer 30 and the passivation layer 28 are etched to form the cavity, which is then filled with the conductive material to form the conductive via structures 32. In one embodiment, the conductive material may be the same material used to form the metallization layer 26, such as the copper-containing material or the aluminum-containing material. In other embodiments, the conductive material may be different from the material of the metallization layer 26, such as tungsten. Chemical mechanical polishing may be used to remove excess conductive material, such that an upper surface of each of the conductive via structures 32 and an upper surface of the second ILD layer 30 are substantially co-planar, as illustrated.

With reference now to FIG. 3, a bottom electrode layer 34 may be formed overlying the upper surfaces of the conductive via structures 32 and the second ILD layer 30 of the MRAM structures 20 to be formed. In certain embodiments, a bottom electrode material is deposited overlying the upper surfaces of the conductive via structures 32 and the second ILD layer 30 to form the bottom electrode layer 34. To this end, the conductive via structures 32 extends through the passivation layer 28 and the second ILD layer 30 to the bottom electrode layer 34 such that the bottom electrode layer 34 overlies and is in electrical communication with the conductive via structures 32. In one embodiment, the bottom electrode layer 34 includes, and/or is formed from, a conductive material. For example, the bottom electrode layer 34 may include, and/or may be formed from, a conductive metal, such as tantalum, tantalum nitride, or titanium, or a combination of one or more thereof.

With continuing reference to FIG. 3, in an exemplary embodiment, a series of material layers 40, 42, 44, 46, and 48 of the MRAM structures 20 are formed overlying one another. As illustrated, a fixed layer 40 is formed overlying the bottom electrode layer 34, a first tunnel barrier layer 42 is formed overlying the fixed layer 40, a free layer 44 is formed overlying the first tunnel barrier layer 42, a second tunnel barrier layer 46 is formed overlying the free layer 44, and a top electrode layer 48 is formed overlying the second tunnel barrier layer 46. While the top electrode layer 48 is illustrated as directly and abuttingly overlying the second barrier layer 46, it will be understood that the top electrode layer 48 may be considered as overlying any of the layers 40 through 44 as well. Layers 40, 42, 44, and 46 form the basis of the MTJ stack of each of the MRAM structures 20 to be formed. The bottom electrode layer 34 is electrically connected to the metallization layer 26 by the conductive via structure 32 and thus to the MTJ stack of the corresponding MRAM structure 20 to be formed. The thicknesses of each such layer 34, 40, 42, 44, 46, and 48 will depend on the overall dimensions of the corresponding MRAM structure 20 to be formed, as well as the operational parameters of the corresponding MRAM structure 20 to be formed, as is known in the art. The processes used for forming such layers are conventional with respect to the particular material selected.

In one embodiment, the fixed layer 40 includes, and/or is formed from, an anti-ferromagnetic material. For example, the fixed layer 40 may include a metal alloy such as platinum manganese (PtMn), iridium manganese (IrMn), nickel manganese (NiMn), or iron manganese (FeMn), or a combination of one or more thereof. It will be appreciated that the fixed layer 40 could include multiple layers such as a synthetic anti-ferromagnetic (SAF) layer to ensure that the fixed layer magnetism is fixed. Other fine-tuning layer(s) to improve coupling could also be added, in an embodiment. The first tunnel barrier layer 42 includes, and/or is formed from, an insulating tunnel barrier material, such as magnesium oxide, amorphous aluminum oxide, or silicon dioxide, or a combination of one or more thereof. The free layer 44 includes, and/or is formed from, a ferromagnetic material. For example, the free layer 44 may include a metal alloy such as cobalt iron boron (CoFeB). The second tunnel barrier layer 46, as with the first tunnel barrier layer 42, includes, and/or is formed from, an insulating tunnel barrier material, such as magnesium oxide, amorphous aluminum oxide, or silicon dioxide, or a combination of one or more thereof. Further, the top electrode layer 48, independently from the bottom electrode layer 34, may include, and/or may be formed from, a conductive metal, such as tantalum, tantalum nitride, or titanium, or a combination of one or more thereof.

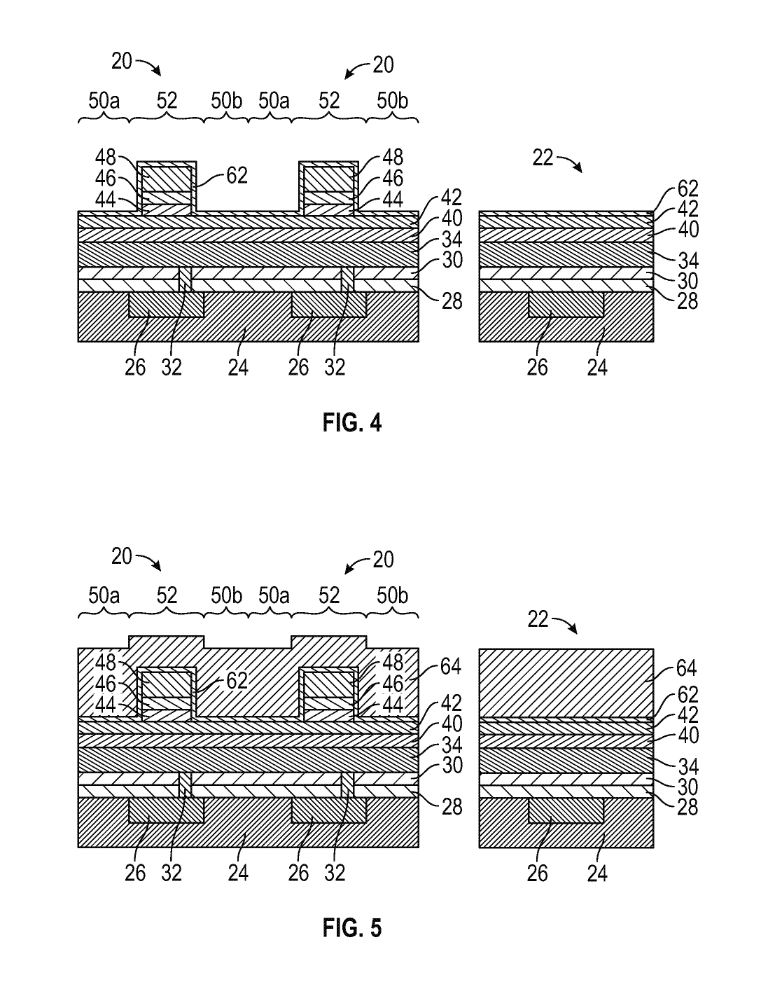

With reference now to FIG. 4, in embodiments, a portion of the free layer 44, a portion of the second tunnel barrier layer 46, and a portion of the top electrode layer 48 is removed, as illustrated. The removed portions of layers 44, 46, and 48 from FIG. 4 are removed from the lateral areas 50a and 50b, as shown in FIG. 4 for each of the MRAM structures 20 to be formed. After such removal, the remaining portion of each of layers 44, 46, and 48 are in a central area 52, which is positioned between the lateral areas 50a and 50b, as illustrated. Additionally, an upper surface of the first tunnel barrier layer 42 is exposed in the lateral areas 50a and 50b. The removal of the portions of layers 44, 46, and 48 may be accomplished using any conventional patterning and etching process. For example, a photoresist layer (not separately illustrated) is deposited over the top electrode layer 48 and then is exposed to an image pattern and treated with a developing solution to form a pattern opening within the photoresist layer. With the photoresist layer thus patterned, the layers 44, 46 and 48 are etched away in the lateral areas 50a and 50b, leaving the layers 44, 46, and 48 remaining in the central area 52. The free layer 44, the second tunnel barrier layer 46, and the top electrode layer 48 each have a width in a width direction (the term “width direction” is used herein with respect to a direction that is substantially parallel to an upper surface of the semiconductor substrate of the integrated circuit 10 as shown in FIGS. 1-11) that is substantially the same with respect to each such layer 44, 46, and 48. That is, a free layer width, a second tunnel barrier layer width, and a top electrode layer width in the width direction are all substantially equal with respect to one another. Additionally, the free layer 44 has free layer sidewalls at lateral ends thereof, the second tunnel barrier layer 46 has second tunnel barrier layer sidewalls at lateral ends thereof, and the top electrode layer 48 has top electrode layer sidewalls at lateral ends thereof. The sidewalls each extend in a direction that is generally perpendicular to the above-described width direction, that is, in a direction perpendicular to the upper surface of the semiconductor substrate of the integrated circuit 10, which is hereinafter referred to as a “sidewall direction.” With the widths of the layers 44, 46, and 48 being substantially the same as described above, the sidewalls are substantially co-planar with one another, as illustrated. FIG. 4 also shows that an encapsulation layer 62 may be formed in-situ with regard to the etch process, for example by conventional conformal deposition processes, over the exposed upper surface of the first tunnel barrier layer 42 in the lateral areas 50a and 50b, along the sidewalls and over the top electrode layer 48 in the central area 52. The encapsulation layer 62 includes a dielectric material, such as a silicon nitride material.

As shown in FIG. 5, a first hardmask layer 64 may be formed overlying the top electrode layer 48 and the encapsulation layer 62 of each of the MRAM structures 20 to be formed. In embodiments, the first hardmask layer 64 is formed of a dielectric material, such as a silicon oxide material, using conventional blanket deposition processes. In this regard, the first hardmask layer 64 also overlies lateral areas 50a and 50b of the layers 34, 40, and 42, wherein, as noted above the lateral areas 50a and 50b of these layers are adjacent to the central area 52 of layers 34, 40, and 42. As illustrated, a portion of the first hardmask layer 64 overlying the central area 52 has a greater height as compared to a height of the other portions of the first hardmask layer 64 overlying the lateral areas 50a and 50b. In embodiments, this difference in height of the first hardmask layer 64 is attributed to the conforming nature of the dielectric material and process utilized to form the first hardmask layer 64. The portion of the first hardmask layer 64 overlying the central area 52 has a first hardmask top surface 66.

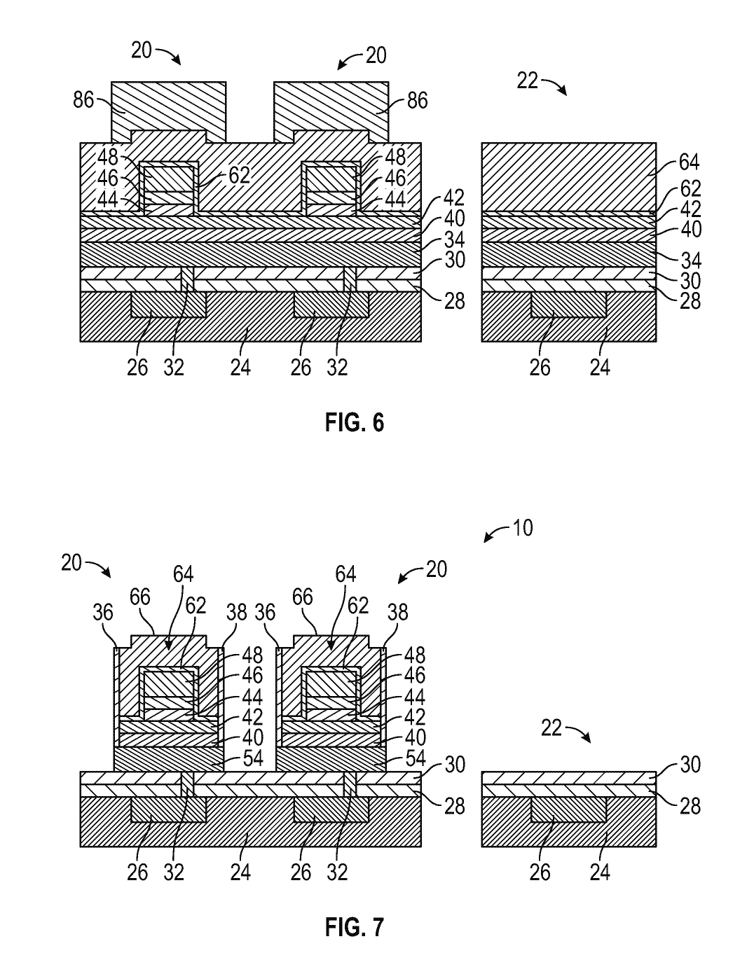

FIGS. 6 and 7 depict the removal of a portion of the bottom electrode layer 34, a portion of the fixed layer 40, a portion of the first tunnel barrier layer 42, a portion of the encapsulation layer 62, and a portion of the first hardmask layer 64. The removal of the portions of layers 34, 40, 42, 62, and 64 may be accomplished using any conventional patterning and etching process. That is, as shown in FIG. 6, a photoresist layer 86 is deposited over the first hardmask layer 64 and then is exposed to an image pattern and treated with a developing solution to form a pattern opening within the photoresist layer 86. With the photoresist layer 86 thus patterned, the portions of layers 34, 40, 42, 62, and 64 are etched away as shown in FIG. 7.

With continuing reference to FIG. 7, the etching thus forms the bottom electrode 54, the fixed layer 40, a first tunnel barrier layer 42, and the first hardmask layer 64 for each of the MRAM structures 20. Additionally, a portion of the upper surface of the second ILD layer 30 is exposed at least between each of the MRAM structures 20. The bottom electrode 54, the fixed layer 40, the first tunnel barrier layer 42, and the first hardmask layer 64 each have a width in the above-described width direction that is substantially the same with respect to each such layer 54, 40, 42, and 64. That is, a bottom electrode width, a fixed layer width, a first tunnel barrier layer width, and a hardmask layer width are all substantially equal with respect to one another. Each of the bottom electrode width, the free layer width, the first tunnel barrier layer width, and the hardmask layer width is wider than each of the free layer width, the second tunnel barrier layer width, and the top electrode layer width. Additionally, the bottom electrode 54 has bottom electrode sidewalls at lateral ends thereof, the fixed layer 40 has fixed layer sidewalls at lateral ends thereof, the first tunnel barrier layer 42 has first tunnel barrier layer sidewalls at lateral ends thereof, and the first hardmask layer 64 has hardmask layer sidewalls at lateral ends thereof. The sidewalls each extend in a direction that is generally perpendicular to the above-described width direction, i.e., in the sidewall direction. With the widths of the layers 54, 40, 42, and 64 being substantially the same as described above, the sidewalls are substantially co-planar with one another, as illustrated.

In embodiments, each of the MRAM structures 20 include a first veil 36 and a second veil 38. The first and second veils 36, 38 may be adjacent the fixed layer 40, the first tunnel barrier layer 42, and the first hardmask layer 64 of each of the MRAM structures 20 with the MTJ stack disposed therebetween. In embodiments, the first veil 36 and the second veil 38 may be formed adjacent to the fixed layer 40, the first tunnel barrier layer 42, and the first hardmask layer 64 as by-products of the etching of the fixed layer 40, the first tunnel barrier layer 42, and the first hardmask layer 64, as described above.

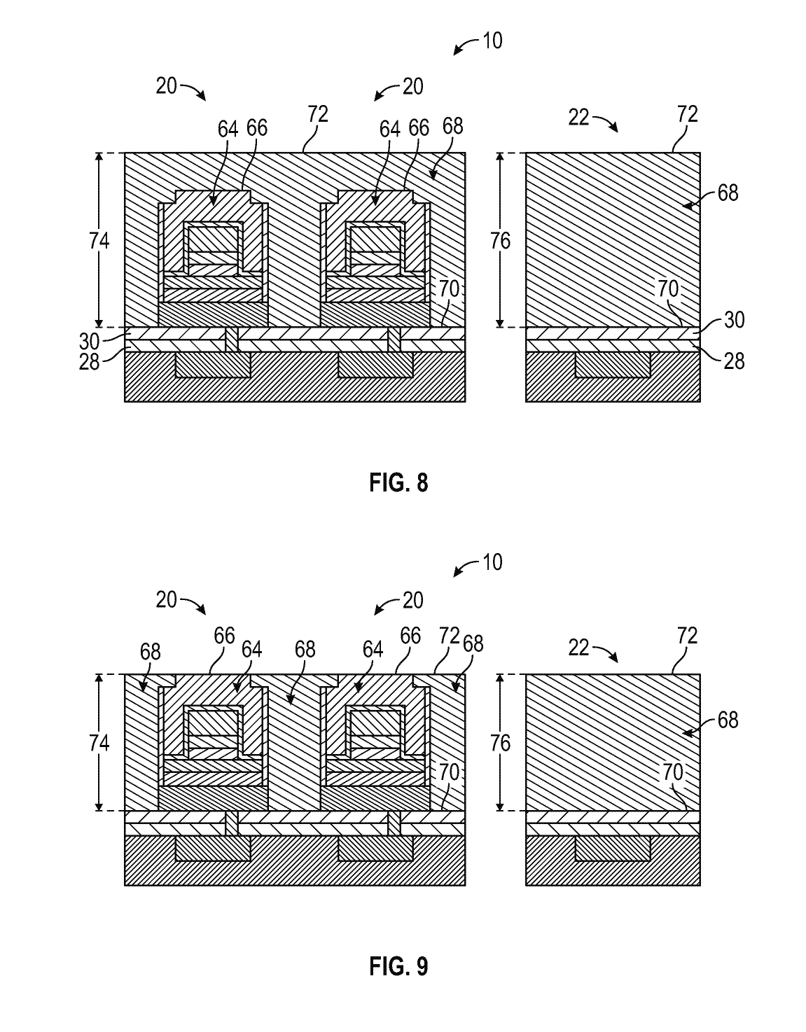

With reference now to FIG. 8, a spin-on dielectric layer 68 is formed at least partially encapsulating the MRAM structures 20 with the spin-on dielectric layer 68 disposed between adjacent MRAM structures 20. The spin-on dielectric layer 68 is also formed overlying the second ILD layer 30 which is proximate the MRAM structures 20. In embodiments including the logic portion 22, the spin-on dielectric layer 68 is formed overlying the second ILD layer 30 which is proximate the logic portion 22. In embodiments, a spin-on dielectric material is deposited overlying the MRAM structures 20 and the second ILD layer 30 to form the spin-on dielectric layer 68. Prior to depositing the spin-on dielectric material, the material may be brought up to room temperature. After reaching room temperature, the material may be heated at about 82° C. for about 1 minute. The material may then be deposited at a spin rate of about 3000 RPM. After deposition of the material, the material may be heated at about 80° C. for about 1 minute, about 150° C. for about 1 minute, and then about 250° C. for about 1 minute. In one embodiment, the material may undergo a high temperature cure by being heated at about 425° C. for 1 hour in the presence of N₂ to cure the material. In another embodiment, the material may undergo a low temperature cure by being heated at about 250 to about 280° C. for about 1 hour in the presence of N₂ to cure the material. In exemplary embodiments, the spin-on dielectric material includes a spin-on-glass (SOG) material. An example of a SOG material is commercially available from Honeywell International Inc. (Morris Plains, N.J., USA) under the trade name of ACCUFLO®.

Without being bound to theory, it is believed that deposition of the spin-on dielectric material on a non-uniform substrate, such as an integrated circuit 10 including the plurality of MRAM structures 20 and the logic portion 22, results in the spin-on dielectric layer 68 having a planar surface without the use of planarization processes, such as chemical-mechanical planarization (CMP). In various embodiments, the spin-on dielectric layer 68 has a spin-on dielectric bottom surface 70 adjacent the bottom electrode layer 34 and a spin-on dielectric top surface 72 opposite the spin-on dielectric bottom surface 70 with a first spin-on dielectric height 74 defined therebetween proximate the MRAM structures 20 and a second spin-on dielectric height 76 defined therebetween proximate the logic portion 22. The first spin-on dielectric height 74 is substantially the same as the second spin-on dielectric height 76. Further, without being bound to theory, it is believed that because a planarization process, such as CMP, is not utilized to planarize the spin-on dielectric layer 68, delamination of MTJ pillars from the MRAM structures 20 due to these planarization processes is prevented and magnetic degradation of the free layer 44 due to pressures resulting from these planarization processes is also prevented. Moreover, without being bound to theory, it is believed that deposition of the spin-on dielectric material on a non-uniform substrate, such as an integrated circuit 10 including the plurality of MRAM structures 20 and the logic portion 22, results in the spin-on dielectric layer 68 being substantially free of gaps without the need for a subsequent deposition of the spin-on dielectric material.

With reference now to FIG. 9, the spin-on dielectric layer 68 may be etched to expose the first hardmask top surface 66 of the first hardmask layer 64. In embodiments, the spin-on dielectric layer 68 is etched proximate both the MRAM structures 20 and the logic portion 22 such that the first spin-on dielectric height 74 remains substantially the same as the second spin-on dielectric height 76. The spin-on dielectric layer 68 may be etched utilizing a soft O₂ plasma etch, such that the spin-on dielectric top surface 72 and the first hardmask top surface 66 are substantially co-planar, as illustrated.

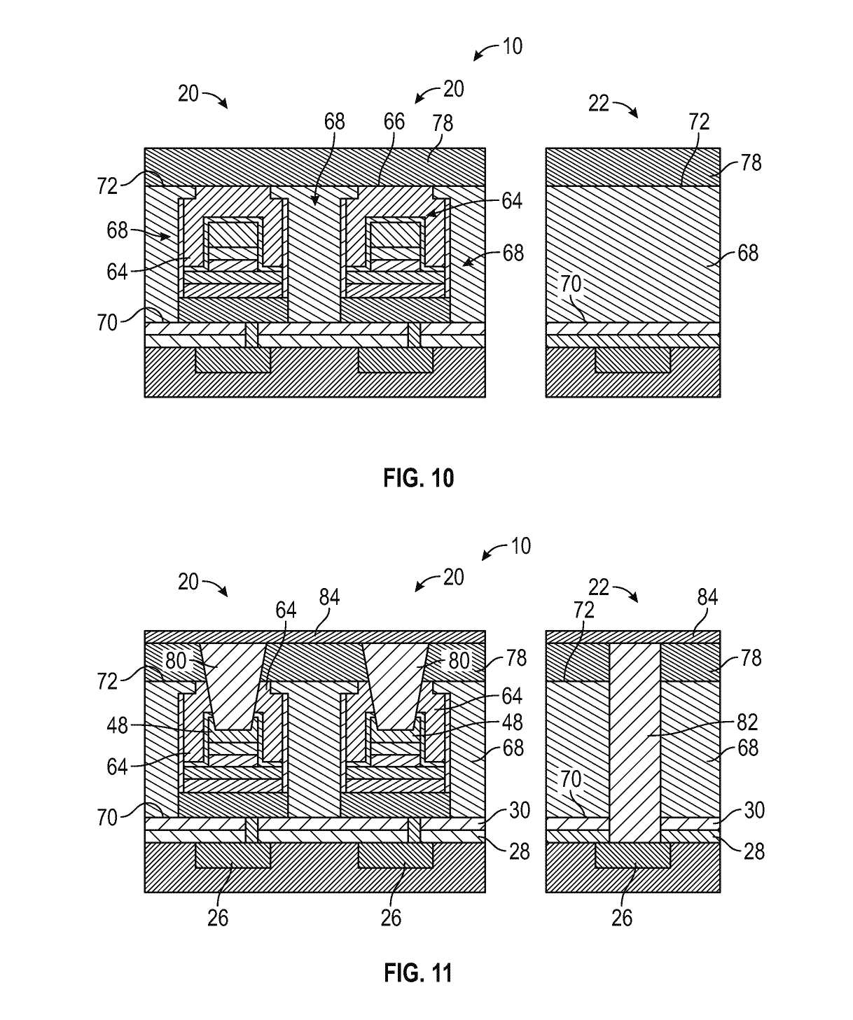

With reference now to FIG. 10, a second hardmask layer 78 may be formed overlying the first hardmask layer 64. In particular, the second hardmask layer 78 may be formed overlying and in direct contact with the first hardmask top surface 66 and the spin-on dielectric top surface 72. In one embodiment, the second hardmask layer 78 is formed of one or more low-k dielectric materials, and/or materials such as un-doped silicate glass (USG), silicon nitride, silicon oxynitride, or other commonly used materials. The dielectric constants (k value) of the low-k dielectric materials may be less than about 3.9, for example, less than about 2.8. The second hardmask layer 78 is formed using conventional deposition techniques, which depend on the particular material employed. In an exemplary embodiment, the second hardmask layer 78 includes, and/or is formed from, a silicon oxide material and is formed by chemical vapor deposition (CVD) process or a plasma-enhanced CVD process in which tetraethyl orthosilicate (TEOS) is used as a reactant.

With reference now to FIG. 11, a contact 80 may be formed on the top electrode layer 48 with the contact 80 extending through the first hardmask layer 64 and the second hardmask layer 78. The contacts 80 may be disposed on and in electrical communication with the top electrode layer 48. Each of the contacts 80 may be formed by etching a trench (not shown) through the first hardmask layer 64 and the second hardmask layer 78 to expose the top electrode layer 48 and filling the trench with a conductive material. In this regard, known photolithographic patterning and etching procedures are used to form the trench through the first hardmask layer 64 and the second hardmask layer 78. That is, a photoresist layer (not separately illustrated) is deposited overlying the second hardmask layer 78 and then is exposed to form an image pattern, followed by application of a developing solution to form pattern openings within the photoresist layer. With the photoresist layer thus patterned, the first hardmask layer 64 and the second hardmask layer 78 are etched to form the trench, which is then filled with the conductive material to form the contacts 80. In one embodiment, the conductive material may be the same material used in to form the metallization layer 26, such as the copper-containing material or the aluminum-containing material. In other embodiments, the conductive material may be different from the material of the metallization layer 26. Chemical mechanical polishing may be used to remove excess conductive material, such that an upper surface of each of the contacts 80 and an upper surface of the second hardmask layer 78 are substantially co-planar, as illustrated.

A through via interconnect 82 may be formed on the metallization layer 26 proximate the logic portion 22. The through via interconnect 82 is disposed on and in electrical communication with the metallization layer 26 proximate the logic portion 22. The through via interconnect 82 is formed by etching a trench through the second hardmask layer 78, the spin-on dielectric layer 68, the second ILD layer 30, and the passivation layer 28 to expose the metallization layer 26 and filling the trench with a conductive material. In one embodiment, the conductive material may be the same material used in to form the metallization layers 26, such as the copper material or the aluminum material. In other embodiments, the conductive material may be different. Chemical mechanical polishing may be used to remove excess conductive material, such that an upper surface of through via interconnect 82 and an upper surface of the second hardmask layer 78 are substantially co-planar, as illustrated.

With continuing reference to FIG. 11, an etch stop layer 84 may be formed overlying the contacts 80. This is an etch stop layer (SiN, e.g.) for the following Far BEOL process. The FBEOL process is not drown here. In particular, the etch stop layer 84 may be formed overlying and in direct contact with the contacts 80, the second hardmask layer 78, and through via interconnect 82. In one embodiment, the etch stop layer 84 is formed of one or more low-k dielectric materials, un-doped silicate glass (USG), silicon nitride, silicon oxynitride, or other commonly used materials. The dielectric constants (k value) of the low-k dielectric materials may be less than about 3.9, for example, less than about 2.8. The etch stop layer 84 is formed using conventional deposition techniques, which depend on the particular material employed. In an exemplary embodiment, the etch stop layer 84 includes, and/or is formed from, silicon nitride. FBEOL processing may proceed after formation of the etch stop layer 84.

The present disclosure may be embodied in other specific forms without departing from the spirit or essential characteristics thereof. The foregoing embodiments, therefore, are to be considered in all respects illustrative rather than limiting. The scope of the subject matter is thus indicated by the appended claims, rather than by the foregoing description, and all changes that come within the meaning and range of equivalency of the claims are intended to be embraced therein.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration as claimed in any way. Rather, the foregoing detailed description will provide those skilled in the art with a convenient road map for implementing the exemplary embodiment or exemplary embodiments. It should be understood that various changes can be made in the function and arrangement of elements without departing from the scope herein as set forth in the appended claims and the legal equivalents thereof.

1. An integrated circuit, comprising:
a plurality of magnetic random access memory (MRAM) structures, wherein each of said MRAM structures comprises;
a bottom electrode,
a magnetic tunnel junction stack (MTJ stack) overlying and in electrical communication with said bottom electrode layer, and
a top electrode layer overlying and in electrical communication with said MTJ stack; and
a spin-on dielectric layer at least partially encapsulating said MRAM structures with said spin-on dielectric layer disposed between adjacent MRAM structures;
wherein said MRAM structure further comprises a contact disposed on said top electrode layer; and
wherein said MRAM structure further comprises a first hardmask layer overlying said top electrode layer with said contact extending through said first hardmask layer.

2. (canceled)

3. (canceled)

4. The integrated circuit of claim 3, wherein said MRAM structure further comprises a second hardmask layer overlying said first hardmask layer with said contact extending through said second hardmask layer.

5. The integrated circuit of claim 3, further comprising:
a first interlayer dielectric layer (ILD layer);
a metallization layer disposed within said first ILD layer; and
a conductive via structure disposed on and in electrical communication with said metallization layer;
wherein said bottom electrode overlies and is in electrical communication with said conductive via structure.

6. The integrated circuit of claim 5, further comprising:
a passivation layer overlying said metallization layer; and
a second ILD layer overlying said passivation layer with said bottom electrode overlying said second ILD layer;
wherein said conductive via structure extends through said passivation layer and said second ILD layer to said bottom electrode.

7. The integrated circuit of claim 1, further comprising a logic portion with said spin-on dielectric layer at least partially encapsulating said logic portion.

8. The integrated circuit of claim 7, wherein said spin-on dielectric layer has a spin-on dielectric bottom surface adjacent said bottom electrode layer and a spin-on dielectric top surface opposite said spin-on dielectric bottom surface with a first spin-on dielectric height defined therebetween proximate said MRAM structure and a second spin-on dielectric height defined therebetween proximate said logic portion, and said first spin-on dielectric height is substantially the same as said second spin-on dielectric height.

9. The integrated circuit of claim 1, wherein said MTJ stack comprises:
a fixed layer overlying said bottom electrode;
a first tunnel barrier layer overlying said fixed layer;
a free layer overlying said first tunnel barrier layer; and
a second tunnel barrier layer overlying said free layer.

10. The integrated circuit of claim 9, wherein said MRAM structure further comprises a first veil and a second veil adjacent to said fixed layer, said first tunnel barrier layer, and said first hardmask layer with said MTJ stack disposed therebetween.

11. A method for fabricating an integrated circuit comprising a plurality of magnetic random access memory (MRAM) structures, said method comprising:
forming the MRAM structures comprising;
forming a bottom electrode layer;
forming a magnetic tunnel junction stack (MTJ stack) overlying and in electrical communication with the bottom electrode layer,
forming a top electrode layer overlying and in electrical communication with the MTJ stack, and
forming a first hardmask layer overlying the top electrode layer with the first hardmask layer; and
depositing a spin-on dielectric material to form a spin-on dielectric layer at least partially encapsulating the MRAM structures with the spin-on dielectric layer disposed between adjacent MRAM structures.

12. The method of claim 11, wherein the first hardmask layer has a first hardmask top surface.

13. The method of claim 12, further comprising etching the spin-on dielectric layer to expose the first hardmask top surface of the first hardmask layer.

14. The method of claim 12, further comprising forming a second hardmask layer overlying the top surface of the first hardmask layer.

15. The method of claim 14, wherein forming the MRAM structures further comprises forming a contact on the top electrode layer, the contact extending through the first hardmask layer and the second hardmask layer.

16. The method of claim 12, wherein forming the MTJ stack comprises:
forming a fixed layer overlying the bottom electrode layer;
forming a first tunnel barrier layer overlying the fixed layer;
forming a free layer overlying the first tunnel barrier layer; and
forming a second tunnel barrier layer overlying the free layer.

17. The method of claim 16, wherein forming the MRAM structures further comprises etching the fixed layer, the first tunnel layer, and the first hardmask layer to form a first veil and a second veil adjacent the fixed layer, the first tunnel layer, and the first hardmask layer with the MTJ stack therebetween.

18. The method of claim 11, wherein the integrated circuit further comprises a logic portion, and depositing the spin-on dielectric material further comprises depositing the spin-on dielectric material to form the spin-on dielectric layer at least partially encapsulating the logic portion.

19. The method of claim 11, wherein forming the MRAM structures further comprises:
depositing a bottom electrode material to form a bottom electrode layer; and
etching a portion of the bottom electrode layer between adjacent MRAM structures to form a bottom electrode.

20. The method of claim 11, further comprising:
forming a first interlayer dielectric layer (ILD layer);
forming a metallization layer disposed within the first ILD layer; and
forming a conductive via structure disposed on and in electrical communication with the metallization layer;
wherein the bottom electrode layer overlies and is in electrical communication with the conductive via structure.

21. The integrated circuit of claim 1, wherein said spin-on dielectric layer is formed from a spin-on dielectric material comprising a spin-on-glass (SOG) material.
